(19) United States
(12) Patent Application Publication
(10) Pub. No.: US 2014/0078678 A1
(43) Pub. Date: Mar. 20, 2014

(54) ELECTRONIC DEVICE WITH HEAT DISSIPATING MODULE

(71) Applicant: HON HAI PRECISION INDUSTRY CO., LTD., New Taipei (TW)

(72) Inventors: Chih-Hang CHAO, New Taipei (TW); Wei-Cheng CHENG, New Taipei (TW); Chih-Hsiang CHIANG, New Taipei (TW)

(73) Assignee: HON HAI PRECISION INDUSTRY CO., LTD., New Taipei (TW)

(21) Appl. No.: 13/870,982

(22) Filed: Apr. 26, 2013

(30) Foreign Application Priority Data
Sep. 14, 2012 (TW) 101133902

(51) Int. Cl. H05K 7/20

(52) U.S. Cl. CPC H05K 7/2039
USPC 361/720

(57) ABSTRACT

An electronic device includes a circuit board, a heat dissipating module, and a latch member. A heat generating part is located on the circuit board. The heat dissipating module includes a plurality of heat pipes and a heat sink. The heat sink abuts the heat generating part, and the plurality of heat pipes abuts the heat sink. The latch member clips the heat sink, to prevent the heat sink from disengaging from the heat generating part, and the plurality of heat pipes are clipped between the heat sink and the latch member.

### BACKGROUND

1. Technical Field

The present disclosure relates to electronic devices, and particularly to an electronic device with a heat dissipating module.

2. Description of Related Art

Circuit boards, such as a motherboard, are located in an enclosure of a server or a computer. A plurality of heat generating components may be located on the circuit board. A typical heat dissipating module is installed on the circuit board for dissipating heat generated by the heat generating parts. The heat dissipating module may include a heat dissipating device, a heat pipe located on the heat dissipating device, and a plurality of heating pieces attached to the heat pipe. Each of the heat dissipating modules abuts each of the heat generating components and is secured to the corresponding heat generating components by a plurality of screws. However, assembly or disassembly of the heat dissipating pieces is very time-consuming and inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding components throughout the several views.

FIG. 1 is an exploded, isometric view of an embodiment of an electronic device.

FIG. 2 is an isometric view of a latch member of FIG. 1.

FIG. 3 is an assembled view of the electronic device of FIG. 1.

FIG. 4 is a cross-sectional view of the electronic device of FIG. 3, taken along the line IV-IV.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

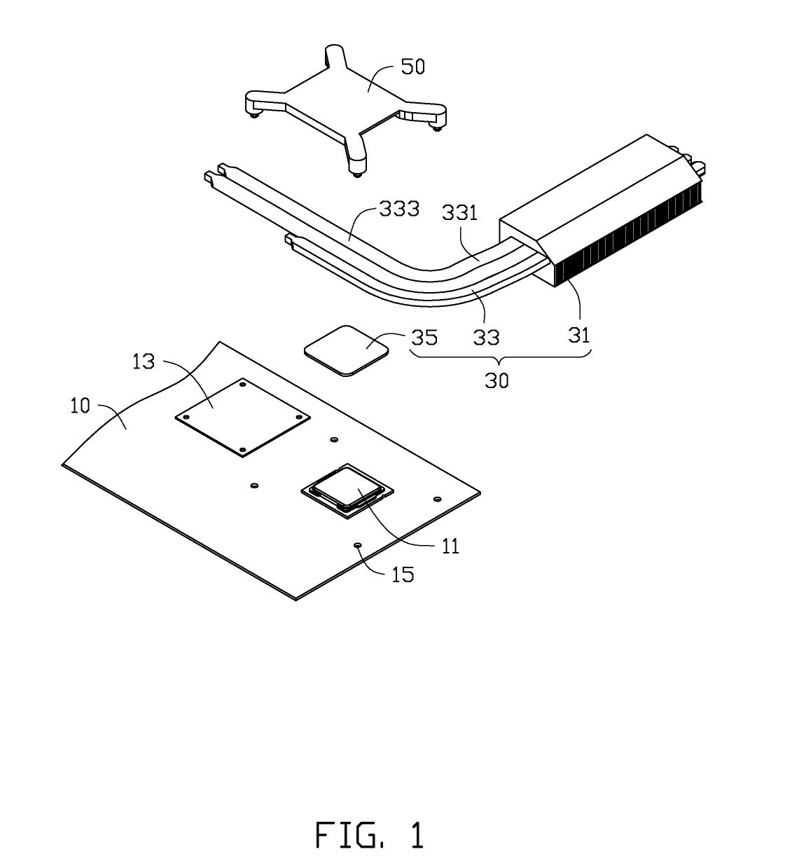

FIG. 1 illustrates an electronic device of one embodiment includes a circuit board 10, a heat dissipating module 30, and a latch member 50. In one embodiment, the circuit board 10 is a mother board of a server or a computer.

A first heat generating part 11 and a second heat generating part 13 are positioned on the circuit board 10. The first heat generating part 11 may be a CPU of a computer, and the second heat generating part 13 may be an expansion chip. Four through holes 15 are defined in the circuit board 10 and arranged at four corners of the first heat generating part 11.

The heat dissipating module 30 includes a plurality of fins 31, a plurality of heat pipes 33, and a heat sink 35. Each of the plurality of heat pipes 33 includes a first section 331 and a second section 333, extending from the first section 331. The first section 331 of the plurality of heat pipes 33 are inserted into the plurality of fins 31, and the second section 333 of the plurality of heat pipes 33 are above the first heat generating part 11 and the second heat generating part 13, for dissipating heat generated by the first heat generating part 11 and the second heat generating part 13.

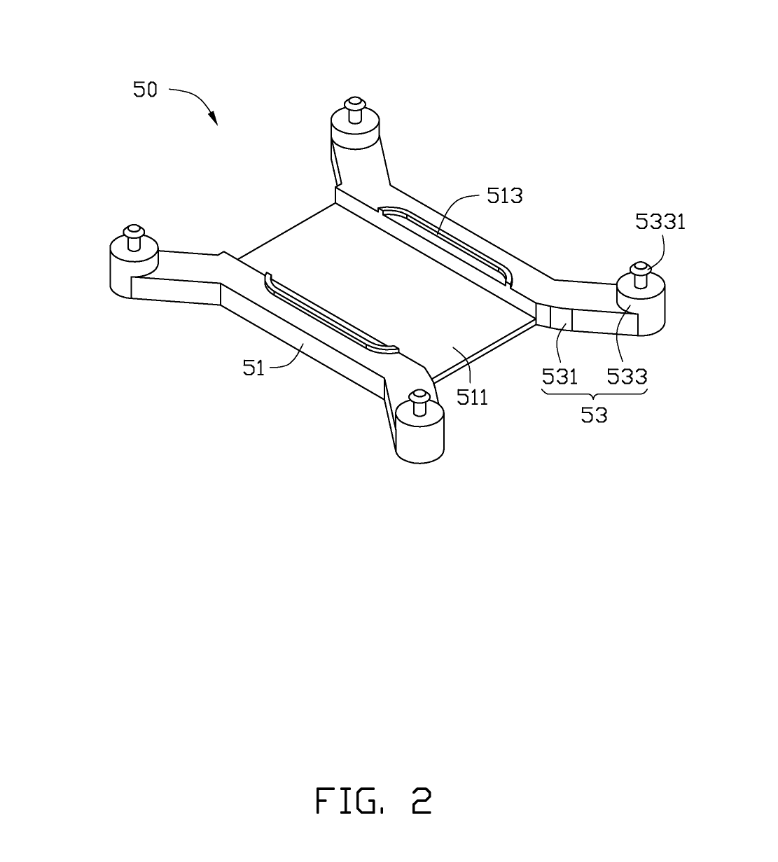

FIG. 2 shows that, the latch member 50 includes a resisting board 51 and four engaging pins 53. The resisting board 51 defines an accommodation slot 511 for receiving the plurality of heat pipes 33. Two protrusion flanges 513 are located on the resisting board 51 and arranged at two opposite edges of the accommodation slot 511, to cooperatively clamp the heat sink 35. In one embodiment, the resisting board 51 is substantially rectangular, and each of the two protrusion flanges 513 is substantially arc-shaped. The four engaging pins 53 are arranged at four corners of the resisting board 51, and each of the four engaging pins 53 includes a connecting arm 531 and an insertion portion 533. The connecting arm 531 horizontally extends from the resisting board 51. The insertion portion 533 is located on a distal end of the connecting arm 531 and extends towards the circuit board 10. A latch portion 5331 is located on a distal end of the insertion portion 533.

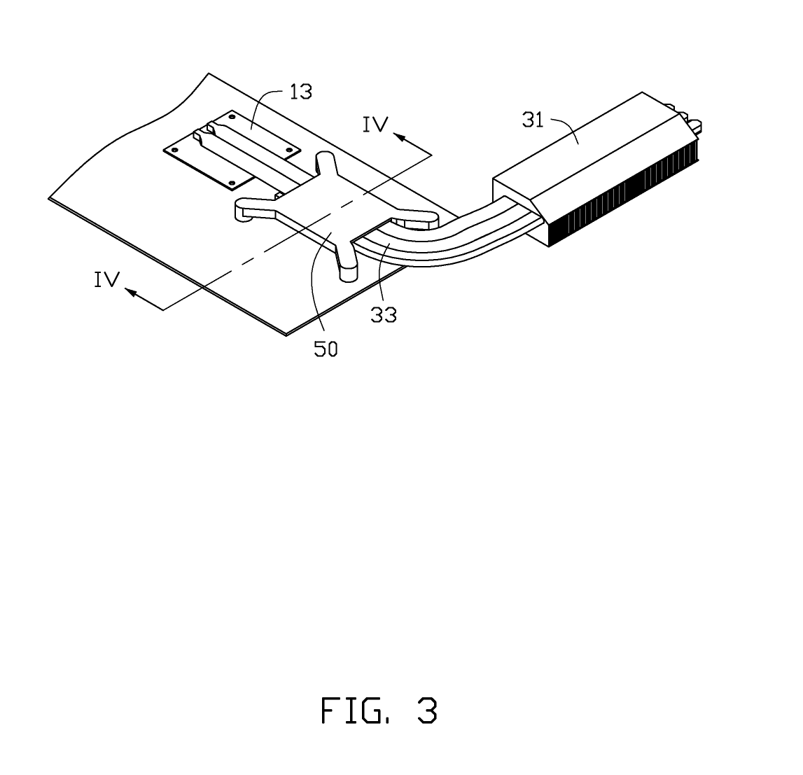

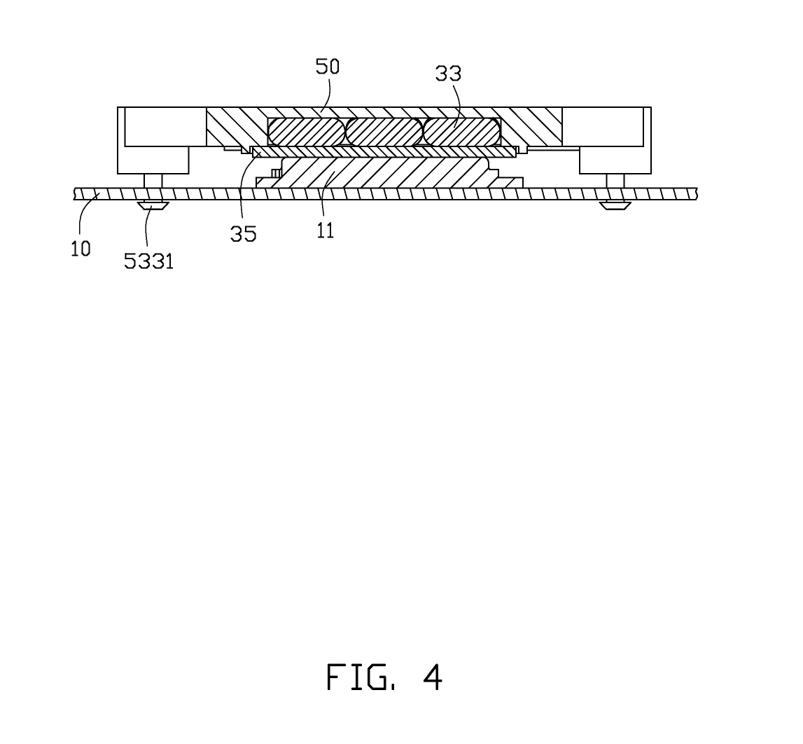

FIGS. 3 and 4 show that in assembly, the plurality of fins 31 are secured to one side of the circuit board 10 via ways well known in the art, such as a screw, or a bolt for example. The heat sink 35 is placed above the first heat generating part 11, and the second section 333 of the plurality of heat pipes 33 are placed above the heat sink 35 and the second heat generating part 13. The latch portion 5331 of each of the four engaging pins 53 is aligned with each of the four through holes 15, and the latch portion 5331 is deformed to extend through the corresponding through hole 15 and engaged with the circuit board 10, to secure the latch member 50 to the circuit board 10. The second section 333 of the plurality of heat pipes 33 are thereby received in the accommodation slot 511, and the heat sink 35 is clipped between the two protrusion flanges 513 and positioned between the second section 333 of the plurality of heat pipes 33 and the first heat generating part 11. The heat sink 35 conducts heat generated by the first heat generating part 11 to the plurality of heat pipes 33, and the plurality of fins 31 dissipates heat in the plurality of heat pipes 33.

In disassembly of the latch member 50, the latch portion 5331 of the four engaging pins 53 is squeezed to be deformed to disengage from each through hole 15.

The plurality of heat pipes 33 and the heat sink 35 are thereby detached easily.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of components within the principles of the disclosure to the full extent indicated by the broad general meaning of the terms in which the appended claims are expressed.

What is claimed is:

1. An electronic device comprising:
a circuit board, a heat generating part being located on the circuit board;
a heat dissipating module comprising a plurality of heat pipes and a heat sink, the heat sink abuts the heat sink, and the plurality of heat pipes abuts the heat sink; and
a latch member engaged with the circuit board,
wherein the latch member prevents the heat sink from disengaging from the heat generating part, and the plurality of heat pipes are clipped between the heat sink and the latch member.

2. The electronic device of claim 1, wherein the circuit board defining at least two through holes, the latch member comprising at least two engaging pins, and each of the at least two engaging pins is engaged in each of the at least two through holes.

3. The electronic device of claim 2, wherein each of the at least two engaging pins comprises a latch portion, and each latch portion extends through each through hole to be engaged with the circuit board.

4. The electronic device of claim 2, wherein the circuit board further comprises a resisting board, the resisting board defines an accommodation slot, and the plurality of heat pipes are received in the accommodation slot.

5. The electronic device of claim 4, wherein the at least two engaging pins are arranged at diagonal of the resisting board, and the at least two through holes are arranged at diagonal of the heat generating part.

6. The electronic device of claim 4, wherein each of the at least two engaging pins comprises a connecting arm and an insertion portion located on a distal end of the connecting arm, the connecting arm extends from the resisting board, and each insertion portion is engaged in each through hole.

7. The electronic device of claim 4, wherein two protrusion flanges are located on two opposite edges of the accommodation slot, and the heat sink is engaged between the two protrusion flanges.

8. The electronic device of claim 7, wherein each of the two protrusion flanges is substantially arc-shaped.

9. An electronic device comprising:
a circuit board defining at least two through holes, a heat generating part being located on the circuit board;
a heat dissipating module comprising a plurality of heat pipes and a heat sink, the heat sink abuts the heat sink, and the plurality of heat pipes abuts the heat sink; and
a latch member comprising at least two engaging pins, and each of the at least two engaging pins being engaged with each of the at least two through holes,
wherein the latch member clips the heat sink, to prevent the heat sink from disengaging from the heat generating part, and the plurality of heat pipes are clipped between the heat sink and the latch member.

10. The electronic device of claim 9, wherein each of the at least two engaging pins comprises a latch portion, and each latch portion extends through each through hole to be engaged with the circuit board.

11. The electronic device of claim 10, wherein the circuit board further comprises a resisting board, the resisting board defines an accommodation slot, and the plurality of heat pipes are received in the accommodation slot.

12. The electronic device of claim 11, wherein each of the at least two engaging pins further comprises a connecting arm and an insertion portion located on distal of the connecting arm, the connecting arm extends from the resisting board, and each insertion portion is engaged in each through hole.

13. The electronic device of claim 12, wherein each latch portion is located on a distal end of each insertion portion.

14. The electronic device of claim 11, wherein two protrusion flanges are located on two opposite edges of the accommodation slot, and the heat sink is engaged between the two protrusion flanges.

15. The electronic device of claim 14, wherein each of the two protrusion flanges is substantially arc-shaped.

16. The electronic device of claim 11, wherein the at least two engaging pins are arranged at diagonal of the resisting board, and the at least two through holes are arranged at diagonal of the heat generating part.
